(19) United States
(12) Patent Application Publication
(10) Pub. No.: US 2026/0068461 A1
(43) Pub. Date: Mar. 5, 2026

(54) LIGHT EMITTING DISPLAY APPARATUS

(71) Applicant: LG Display Co., Ltd., Seoul (KR)

(72) Inventor: Youngwan KIM, Paju-si (KR)

(73) Assignee: LG Display Co., Ltd., Seoul (KR)

(21) Appl. No.: 19/280,005

(22) Filed: Jul. 24, 2025

(30) Foreign Application Priority Data
Aug. 29, 2024 (KR) 10-2024-0116660

(51) Int. Cl. H10K 59/131; G09G 3/3225; H10D 86/40; H10D 86/60; H10K 59/121; H10K 102/00

(52) U.S. Cl. CPC H10K 59/131; G09G 3/3225; H10K 59/1213; G09G 2330/08; G09G 2330/12; H10D 86/443; H10D 86/60; H10K 2102/341

(57) ABSTRACT

A light emitting display apparatus according to one or more embodiments of the present disclosure may include a light emitting element including a pixel electrode, an emission layer, and a common electrode, and a pixel circuit connected to the pixel electrode and configured to include at least one thin film transistor, the pixel electrode may include a first pixel divided electrode and a second pixel divided electrode spaced apart from each other, the first pixel divided electrode may be electrically connected to the pixel circuit through a first branch pattern having a first sensing node, and the second pixel divided electrode may be electrically connected to the pixel circuit through a second branch pattern having a second sensing node different from the first sensing node.

### CROSS-REFERENCE TO RELATED APPLICATIONS

This application claims the benefit of and priority to Korean Patent Application No. 10-2024-0116660 filed in Republic of Korea on Aug. 29, 2024, the entirety of which is incorporated herein by reference for all purposes.

### BACKGROUND

### Technical Field

The present disclosure relates to a light emitting display apparatus.

### Description of the Related Art

With the development of information society, the demand for a display apparatus for displaying an image is increasing in various forms. Accordingly, display apparatuses such as a liquid crystal display (LCD) apparatus, an organic light emitting display (OLED) apparatus, a micro light emitting diode LED display apparatus, a quantum dot display (QD) apparatus, and the like are used.

Among the display apparatuses, the organic light emitting display apparatus is a self-luminous type. In the organic light emitting display apparatus, hole and electron are injected into an emission layer from an anode electrode for hole injection and a cathode electrode for electron injection, and the injected hole and electron are bonded to each other. Herein, when the bonded hole and electron exciton fall from the excited state to the ground state, the organic light emitting display apparatus may emit light and display an image.

The organic light emitting display apparatus has a problem in that dark spots may occur due to the generation of foreign substances between the anode electrode and the cathode electrode in a process of forming the cathode electrode of light emitting element through a sputtering process.

### SUMMARY

One or more embodiments of the present disclosure may provide a light emitting display apparatus having a repair structure for a short defect between an anode electrode and a cathode electrode.

One or more embodiments of the present disclosure may provide a light emitting display apparatus capable of automatically detecting a defective repair target by configuring individual sensing nodes with the same resistance in divided subpixels for defect repair.

One or more embodiments of the present disclosure may provide a light emitting display apparatus capable of improving the detection reliability of defective repair targets in subpixels through a resistance compensation structure that compensates for resistance variations in individual sensing nodes of divided subpixels.

Additional advantages and features of the disclosure will be set forth in part in the description which follows and in part will become apparent to those having ordinary skill in the art upon examination of the following or may be learned from practice of the disclosure. The objectives and other advantages of the disclosure may be realized and attained by the structure particularly pointed out in the written description and claims hereof as well as the appended drawings.

A light emitting display apparatus according to one or more embodiments of the present disclosure may include a light emitting element including a pixel electrode, an emission layer, and a common electrode, and a pixel circuit connected to the pixel electrode and configured to include at least one thin film transistor, the pixel electrode may include a first pixel divided electrode and a second pixel divided electrode spaced apart from each other, the first pixel divided electrode may be electrically connected to the pixel circuit through a first branch pattern having a first sensing node, and the second pixel divided electrode may be electrically connected to the pixel circuit through a second branch pattern having a second sensing node different from the first sensing node.

According to one or more embodiments of the present disclosure, a light emitting display apparatus having a repair structure for a short defect between an anode electrode and a cathode electrode, may be provided.

According to one or more embodiments of the present disclosure, a light emitting display apparatus capable of automatically detecting a defective repair target by configuring individual sensing nodes with the same resistance in divided subpixels for defect repair, may be provided.

According to one or more embodiments of the present disclosure, a light emitting display apparatus capable of improving the detection reliability of defective repair targets in subpixels through a resistance compensation structure that compensates for resistance variations in individual sensing nodes of divided subpixels, may be provided.

The light emitting display apparatus according to one or more embodiments of the present disclosure may improve production yield by reducing the tact time of the repair process through an accurate detection of the defective repair targets and improving the reliability of manufacturing process, whereby it is possible to implement Environment/Social/Governance (ESG) by reducing the generation of greenhouse gas that may occur due to the manufacturing process.

The effects of the present disclosure are not limited to the aforesaid, but other effects not described herein will be clearly understood by those skilled in the art from the following descriptions.

The details of the present disclosure described in technical problem, technical solution, and advantageous effects do not specify essential features of claims, and thus, the scope of claims is not limited by the details described in detailed description of the disclosure.

### BRIEF DESCRIPTION OF THE DRAWINGS

The accompanying drawings, which are included to provide a further understanding of the disclosure, are incorporated in and constitute a part of this disclosure, illustrate aspects and embodiments of the disclosure, and together with the description serve to explain the principles and examples of the disclosure.

FIG. 1 illustrates a light emitting display apparatus according to an embodiment of the present disclosure.

FIG. 2 is a circuit diagram illustrating a subpixel of a light emitting display apparatus according to an embodiment of the present disclosure.

FIG. 3 illustrates a pixel of a light emitting display apparatus according to an embodiment of the present disclosure.

FIG. 4 illustrates a region A shown in FIG. 3 according to an embodiment of the present disclosure.

FIG. 5 illustrates a region B shown in FIG. 4 according to an embodiment of the present disclosure.

FIG. 6 is a cross-sectional view taken along line I-I′ of FIG. 5 according to an embodiment of the present disclosure.

FIG. 7 is a cross-sectional view taken along line II-II′ of FIG. 5 according to an embodiment of the present disclosure.

FIG. 8 illustrates a subpixel and a repair detecting portion in a light emitting display apparatus according to an embodiment of the present disclosure.

FIG. 9 illustrates a region B shown in FIG. 4 according to another embodiment of the present disclosure.

FIG. 10 illustrates a subpixel and a repair detecting portion in a light emitting display apparatus according to another embodiment of the present disclosure.

FIG. 11 illustrates a region B shown in FIG. 4 according to another embodiment of the present disclosure.

FIG. 12 illustrates a subpixel and a repair detecting portion in a light emitting display apparatus according to another embodiment of the present disclosure.

FIG. 13 illustrates a region B shown in FIG. 4 according to another embodiment of the present disclosure.

FIG. 14 illustrates a subpixel and a repair detecting portion in a light emitting display apparatus according to another embodiment of the present disclosure.

Throughout the drawings and the detailed description, unless otherwise described, the same drawing reference numerals should be understood to refer to the same elements, features, and structures. The sizes, lengths, and thicknesses of layers, regions and elements, and depiction of thereof may be exaggerated for clarity, illustration, and/or convenience.

### DETAILED DESCRIPTION OF THE DISCLOSURE

Advantages and features of the present disclosure, and implementation methods thereof, are clarified through the embodiments described with reference to the accompanying drawings. The present disclosure may, however, be embodied in different forms and should not be construed as limited to the embodiments set forth herein. Rather, these embodiments are examples and are provided so that this disclosure may be thorough and complete, to assist those skilled in the art to understand the inventive concepts without limiting the protected scope of the present disclosure.

Shapes (e.g., sizes, lengths, widths, heights, thicknesses, locations, radii, diameters, and areas), sizes, ratios, angles, numbers, and the like disclosed herein, including those illustrated in the drawings are merely examples, and thus, the present disclosure is not limited to the illustrated details. Any implementation described herein as an “example” is not necessarily to be construed as preferred or advantageous over other implementations. It is, however, noted that the relative dimensions of the components illustrated in the drawings are part of the present disclosure.

When the term “comprise,” “have,” “include,” “contain,” “constitute,” “made of,” “formed of,” or the like is used with respect to one or more elements, one or more other elements may be added unless a term such as “only” or the like is used. The terms used in the present disclosure are merely used in order to describe example embodiments, and are not intended to limit the scope of the present disclosure. The terms of a singular form may include plural forms unless the context clearly indicates otherwise.

In construing an element, the element is construed as including an error region although there is no explicit description thereof.

In describing a positional relationship, for example, when the positional order is described as “on,” “above,” “below,” “beneath,” and “next,” the case of no contact therebetween may be included, unless “just” or “direct” is used.

If it is mentioned that a first element is positioned “on” a second element, it does not mean that the first element is essentially positioned above the second element in the figure. The upper part and the lower part of an object concerned may be changed depending on the orientation of the object. Consequently, the case in which a first element is positioned “on” a second element includes the case in which the first element is positioned “below” the second element as well as the case in which the first element is positioned “above” the second element in the figure or in an actual configuration.

In describing a temporal relationship, for example, when the temporal order is described as “after,” “subsequent,” “next,” and “before,” a case which is not continuous may be included, unless “just” or “direct” is used.

It will be understood that, although the terms “first,” “second,” etc., may be used herein to describe various elements, these elements should not be limited by these terms. These terms are only used to distinguish one element from another. For example, a first element could be termed a second element, and, similarly, a second element could be termed a first element.

In describing elements of the present disclosure, the terms “first,” “second,” “A,” “B,” “(a),” “(b),” or the like may be used. These terms are intended to identify the corresponding element(s) from the other element(s), and these are not used to define the essence, basis, order, or number of the elements.

For the expression that an element is “connected,” “coupled,” “attached,” “adhered,” or the like to another element, the element may not only be directly connected, coupled, attached, adhered, or the like to another element, but also be indirectly connected, coupled, attached, adhered, or the like to another element with one or more intervening elements disposed or interposed between the elements, unless otherwise specified.

For example, the phrase “A is connected to B” encompasses both a direct connection—where no intervening components or elements are present—and an indirect connection, where one or more intermediate components or elements exist between A and B. In other words, “A is connected to B” includes both direct physical or electrical coupling and indirect coupling through one or more intervening components. Unless explicitly stated otherwise, these terms do not require direct physical or electrical contact. The term “coupled” and other terms listed above should be interpreted in the same manner.

For the expression that an element is “contacts,” “overlaps,” or the like with another element, the element may not only directly contact, overlap, or the like with another element, but also indirectly contact, overlap, or the like with another element with one or more intervening elements disposed or interposed between the elements, unless otherwise specified.

The term “at least one” should be understood as including any and all combinations of one or more of the associated listed items. For example, “at least one among a first element, a second element and a third element” may include all combinations of two or more elements selected from the first, second and third elements as well as each element of the first, second and third elements.

Features of various embodiments of the present disclosure may be partially or entirety coupled to or combined with each other, may be technically associated with each other, and may be variously inter-operated, linked or driven together. The embodiments of the present disclosure may be implemented or carried out independently of each other, or may be implemented or carried out together in a co-dependent or related relationship. In one or more aspects, the components of each apparatus according to various embodiments of the present disclosure are operatively coupled and configured.

In the following description, various example embodiments of the present disclosure are described in detail with reference to the accompanying drawings. With respect to reference numerals to elements of each of the drawings, the same elements may be illustrated in other drawings, and like reference numerals may refer to like elements unless stated otherwise. The same or similar elements may be denoted by the same reference numerals even though they are depicted in different drawings. In addition, for convenience of description, a scale, dimension, size, and thickness of each of the elements illustrated in the accompanying drawings may be different from an actual scale, dimension, size, and thickness, and thus, embodiments of the present disclosure are not limited to a scale, dimension, size, and thickness illustrated in the drawings.

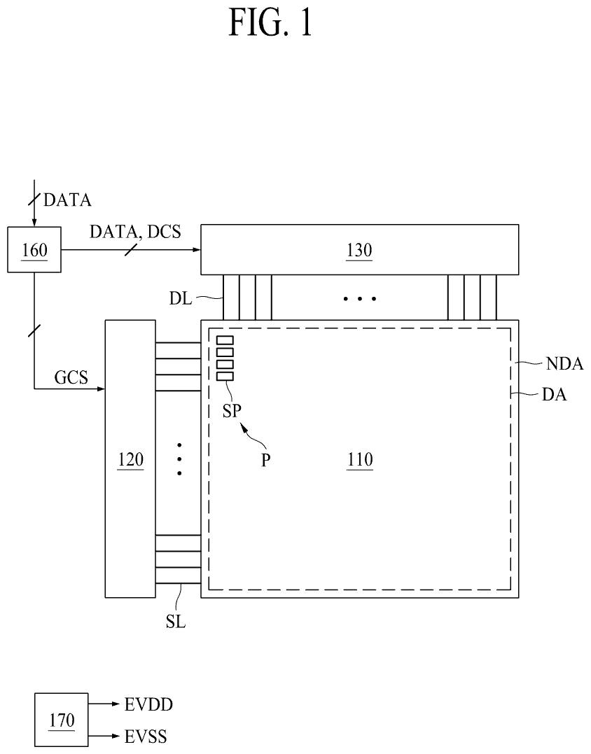

FIG. 1 illustrates a light emitting display apparatus according to an embodiment of the present disclosure.

A light emitting display apparatus according to an embodiment of the present disclosure is implemented as an organic light emitting display apparatus, but may also be implemented as a liquid crystal display apparatus, a quantum dot lighting emitting diode display apparatus, or an electrophoretic display apparatus.

Referring to FIG. 1, the light emitting display apparatus according to an embodiment of the present disclosure may include a display panel 110, a scan driver 120 (or a gate driver) embedded in the display panel 110, a data driver 130 connected to the display panel 110, a timing controller 160 controlling the scan driver 120 and the data driver 130, and a power circuit 170.

The display panel 110 includes a display area DA and a non-display area NDA surrounding the display area DA. The display panel 110 includes pixels P provided in the display area DA to display an image. Each of the pixels P may include a plurality of subpixels SP. The structure of the subpixel SP may be variously changed according to the type of the light emitting display apparatus. For example, the subpixels SP may be formed in a top emission type, a bottom emission type, or a dual emission type according to the structure. The subpixels SP indicate a unit capable of forming a color filter of a specific type or capable of emitting a color of itself without forming a color filter. For example, the subpixels SP may include a red subpixel, a green subpixel, and a blue subpixel. Alternatively, the subpixels SP may include a red subpixel, a blue subpixel, a white subpixel, and a green subpixel. The subpixels SP may have one or more other light-emitting areas according to light-emitting characteristics. For example, the plurality of subpixels SP may be arranged in a quad type or a stripe type, but embodiments of the present disclosure are not limited thereto. The color type, arrangement type, arrangement order, and the like of the subpixels SP may be configured in various forms according to the light-emitting characteristics, lifespan of the apparatus, spec of the apparatus, and the like.

The display panel 110 may include data lines DL and scan lines SL (or gate lines) connected to the subpixels SP. The data lines DL may be arranged to cross the scan lines SL. Each of the subpixels SP of the display panel 110 may be connected to any one of the data lines DL and any one of the scan lines SL. The data lines DL may supply a data voltage supplied from the data driver 130 to each of the subpixels SP. The scan lines SL may supply a scan signal supplied from the scan driver 120 to each of the subpixels SP.

Each of the subpixels SP is turned-on by the scan signal. When the data voltage of the data line DL is supplied to a gate electrode of a driving transistor, a light emitting element may emit light according to a drain-to-source current of the driving transistor. The scan driver 120 may receive a scan control signal GCS from the timing controller 160. The scan driver 120 may supply the scan signals or emission control signal to the scan lines SL by using the scan control signal GCS.

The scan driver 120 may be configured in a gate driver in panel GIP manner in the non-display area NDA outside one side or both sides of the display area DA. Alternatively, the scan driver 120 may be manufactured as a driving chip, mounted on a flexible film, and attached to the non-display area NDA outside one side or both sides of the display area DA in a tape automated bonding TAB manner.

The data driver 130 may receive digital video data DATA and a data control signal DCS from the timing controller 160. The data driver 130 converts the digital video data DATA into analog positive/negative data voltages by using the data control signal DCS and supplies the analog positive/negative data voltages to the data lines DL.

The timing controller 160 receives digital video data DATA and timing signals from a host system. The timing signals may include a vertical synchronization signal, a horizontal synchronization signal, a data enable signal, a dot clock, and the like. The vertical synchronization signal is a signal defining one frame period. The horizontal synchronization signal is a signal defining one horizontal period required for supplying the data voltages to the pixels of one horizontal line of the display panel 110. The data enable signal defines a period in which valid data is input. The dot clock is a signal repeated at a predetermined short period.

The timing controller 160 may generate the data control signal DCS for controlling an operation timing of the data driver 130 and the scan control signal GCS for controlling an operation timing of the scan driver 120 based on the timing signals. The timing controller 160 may output the scan control signal GCS to the scan driver 120 and output the digital video data DATA and data control signal DCS to the data driver 130.

The power circuit 170 may generate and supply a plurality of driving voltages required for an operation of all circuit configurations of the display apparatus by using an input voltage. The power circuit 170 may generate a first power supply voltage EVDD (or pixel power voltage), a second power supply voltage EVSS (or common power voltage) and an initialization voltage Vref (or reference voltage) and supply the generated voltages to the display panel 110. The power circuit 170 may generate and supply various driving voltages required for operations of the gate driver 120, the data driver 130, and the timing controller 160.

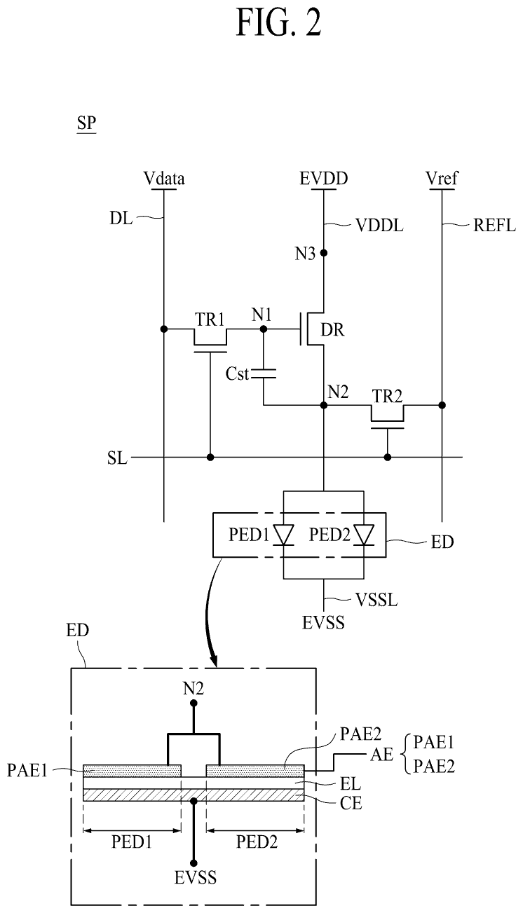

FIG. 2 is a circuit diagram illustrating a subpixel of a light emitting display apparatus according to an embodiment of the present disclosure.

Referring to FIG. 2, each of pixels includes a plurality of subpixels SP constituting a unit pixel. In each of the plurality of subpixels SP, there are a pixel circuit having 3T (Transistor) 1C (Capacitor) including a driving transistor DR, a first switching transistor TR1, a second switching transistor TR2 and a storage capacitor Cst, and a light emitting element ED, but not limited thereto. For example, each subpixel SP may further include a compensation circuit. In this case, the subpixel SP may have various structures such as 4T2C, 5T2C, 6T1C, 6T2C, 7T1C, and 7T2C.

At least one thin film transistor DR, TR1 and TR2 of each subpixel SP may include a gate electrode, a source electrode, and a drain electrode. Since the source electrode and the drain electrode may be changed according to a voltage and a current direction applied to the gate electrode without being fixed, any one of the source electrode and the drain electrode may be represented as a first electrode, and the other may be represented as a second electrode. The at least one transistor DR, TR1, and TR2 may use at least one of polysilicon semiconductor, amorphous silicon semiconductor, and oxide semiconductor. The transistors DR, TR1, and TR2 may be P-type or N-type, or P-type and N-type may be interchangeably used.

The driving transistor DR corresponds to a transistor for driving the light emitting element ED, and the driving transistor DR includes a first node N1 to which a data voltage Vdata is applied, a second node N2 connected to a first electrode AE (pixel electrode or anode electrode) of the light emitting element ED, and a third node N3 connected to a pixel power line VDDL (or first power line) and supplied with a first power supply voltage EVDD (or pixel power voltage). For example, the first node N1 may be a gate node of the driving transistor DR, the second node N2 may be a source or drain node of the driving transistor DR, and the third node N3 may be a source or drain node of the driving transistor DR. For example, the second node N2 may be a source node, and the third node N3 may be a drain node, but embodiments of the present disclosure are not limited thereto.

The first switching transistor TR1 may serve to supply the data voltage Vdata supplied from the data line DL to the driving transistor DR. The first switching transistor TR1 may switch an electrical connection between the data line DL and the first node N1. For example, the first switching transistor TR1 may be turned-on in response to the scan signal Scan applied through a scan line SL (or gate line). When the first switching transistor TR1 is turned-on, the data voltage Vdata applied through the data line DL may be transferred to the first node N1.

The second switching transistor TR2 may serve to supply a reference voltage Vref supplied from a reference line REFL to a driving transistor DR or may output a voltage of a second node N2 of the driving transistor DR. The second switching transistor TR2 may switch an electrical connection between the reference line REFL and the second node N2. For example, the second switching transistor TR2 may be turned-on in response to a scan signal applied through a scan line SL (or gate line). When the second switching transistor TR2 is turned-on, the reference voltage Vref applied through the reference line REFL may be transferred to the second node N2, or when the second switching transistor TR2 is turned-on, the voltage of the second node N2 of the driving transistor DR may be output to the reference line REFL.

The storage capacitor Cst maintains the data voltage Vdata supplied to the driving transistor DR for a period (e.g., one frame). The storage capacitor Cst may be connected between the first node N1 and the second node N2. For example, the storage capacitor Cst may store the voltage corresponding to the data voltage Vdata transferred through the first switching transistor TR1 and may turn on the driving transistor DR with the stored voltage.

The light emitting element ED may include the first electrode AE (pixel electrode or anode electrode) connected to the driving transistor, the second electrode CE (common electrode or cathode electrode) receiving a second power voltage EVSS (or common power voltage) from a common power line VSSL (or second power line), and an emission layer (or organic light emitting layer) between the first electrode AE and the second electrode CE. The first electrode AE is an independent electrode for each light emitting element, but the second electrode CE may be a common electrode shared by the entire light emitting elements. When a driving current is supplied from the driving transistor DR, electrons from the second electrode CE are injected into the emission layer EL, and holes from the first electrode AE are injected into the emission layer EL, whereby fluorescent or phosphorescent materials emit through recombination of electrons and holes in the emission layer EL, thereby generating light of brightness proportional to a current value of the driving current.

The first electrode AE of the light emitting element ED may be connected to the second node N2 of the driving transistor DR, and the second electrode CE of the light emitting element ED may be connected to the common power line VSSL. The light emitting element ED may emit light in response to the driving current generated by the driving transistor DR.

The light emitting element ED according to an embodiment of the present disclosure may comprise a first partial light emitting element PED1 and a second partial light emitting element PED2. The first partial light emitting element PED1 and the second partial light emitting element PED2 may be connected in common to the second node N2 of the driving transistor DR. A first electrode AE of the light emitting element ED may be divided into a first divided electrode PAE1 (or first pixel divided electrode) and a second divided electrode PAE2 (or second pixel divided electrode). A second electrode CE of the light emitting element ED may be connected in common to the first divided electrode PAE1 and the second divided electrode PAE2. The second electrode CE receives a second power voltage EVSS from a common power line VSSL and applies the second power voltage EVSS to the first divided electrode PAE1 and the second divided electrode PAE2.

The first partial light emitting element PED1 may include the first divided electrode PAE1, the emission layer EL, and the second electrode CE. In addition, the second partial light emitting element PED2 may include the second divided electrode PAE2, the emission layer EL, and the second electrode CE. According to an embodiment of the present disclosure, the light emitting element ED of each subpixel SP may include the first partial light emitting element PED1 and the second partial light emitting element PED2 by the first electrode AE divided into the first divided electrode PAE1 and the second divided electrode PAE2.

The light emitting element ED of each subpixel SP according to an embodiment of the present disclosure is configured to be divided into the first partial light emitting element PED1 and the second partial light emitting element PED2. When a short occurs due to foreign substances in any one of the first partial light emitting element PED1 and the second partial light emitting element PED2 during a panel manufacturing process or after completion of panel production, a repair process may be carried out by darkening only the partial light emitting element with the short, and normally operating the remaining partial light emitting element.

The repair process according to an embodiment of the present disclosure may include an aging repair process and a semi-dark repair process for removing an anode-cathode short AC short during the repair process after the panel manufacturing process or after shipping of panel product. For example, the aging repair process may remove the anode-cathode short with Joule Heating that generates heat from an anode-cathode short portion by applying a reverse bias voltage between the second electrode CE and the second node N2 of the driving transistor DR.

The semi-dark repair process checks the anode-cathode short portion, which is not removed by the aging repair process, as naked eyes (or a microscope) of a worker and carries out a cutting process by applying laser or physical force to the divided electrode of the partial light emitting element with the anode-cathode short of the first partial light emitting element PED1 and the second partial light emitting element PED2 of the light emitting element ED, whereby the half (½) of the light emitting element ED may be darkened, and the remaining half (½) of the light emitting element ED may be normally operated. However, in the light emitting display apparatus according to an embodiment of the present disclosure, since a worker observes foreign substances with naked eye in the semi-dark repair process and proceeds with the repair process, a tact time is long. Also, when foreign matters are not seen, a repair success rate is lowered. In addition, another processing anode-cathode short may occur even after the semi-dark repair process is performed so that it is difficult to manage the yield of the light emitting display apparatus. Accordingly, the inventors of the present disclosure have invented a light emitting display apparatus having a new structure, which is capable of automatically detecting a semi-dark repair target for a semi-dark repair process and accurately detecting the semi-dark repair target, through various studies.

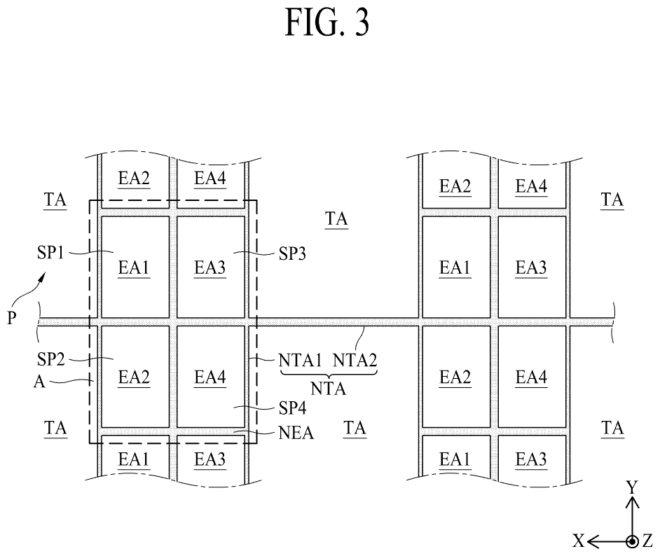

Hereinafter, a light emitting display apparatus according to an embodiment of the present disclosure capable of automatically detecting a semi-dark repair target in a semi-dark repair process and accurately detecting the semi-dark repair target will be described in more detail with reference to FIGS. 3 to 14.

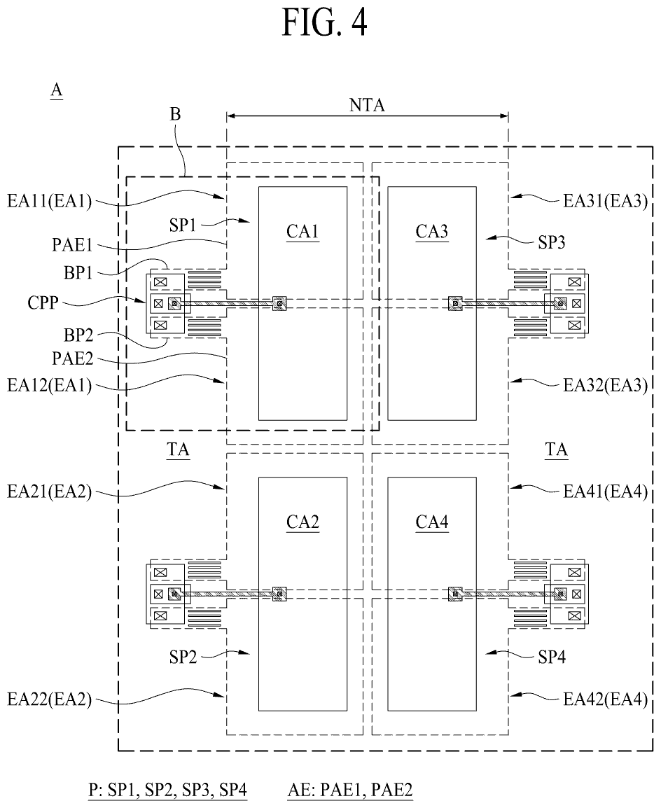

FIG. 3 illustrates a pixel of a light emitting display apparatus according to an embodiment of the present disclosure. FIG. 4 illustrates a region A shown in FIG. 3 according to an embodiment of the present disclosure.

Referring to FIGS. 3 and 4, each of pixels P of the light emitting display apparatus according to an embodiment of the present disclosure may include a transmission area TA and a non-transmission area NTA in which a plurality of subpixels SP1, SP2, SP3, and SP4 representing different colors are disposed. For example, in FIGS. 3 and 4, each pixel P is illustrated as a transparent display panel including a transmission area TA, but embodiments of the present disclosure are not limited thereto. Herein, each pixel P may be a light emitting display panel which does not include a transmission area TA.

Referring to FIG. 3, in each pixel P, the plurality of subpixels SP1, SP2, SP3, and SP4 may be disposed adjacent to each other in a first direction (or Y-axis direction) and a second direction (or X-axis direction). Also, the transmission area TA may be disposed adjacent to the plurality of subpixels SP1, SP2, SP3, and SP4 in a second direction (or X-axis direction). For example, the transmission area TA may be an area through which most of light incident from the outside passes, and the non-transmission area NTA may be an area which does not transmit most of light incident from the outside. For example, the transmission area TA may be an area in which the light transmittance is greater than a %, and the non-transmission area NTA may be a region in which the light transmittance is less than b %. Herein, ‘a’ may be a value greater than ‘b.’ The light emitting display apparatus according to the embodiment of the present disclosure may view an object or a background located on a rear surface (or back surface) of a display panel 110 through transmission areas TA.

The non-transmission area NTA may include a first non-transmission area NTA1, a second non-transmission area NTA2, and the plurality of subpixels SP1, SP2, SP3, and SP4.

The first non-transmission area NTA1 extends in the display panel 110 in the first direction (or Y-axis direction), and at least a portion of the first non-transmission area NTA1 may be disposed to overlap with emission areas EA1, EA2, EA3, and EA4 of each of the subpixels SP1, SP2, SP3, and SP4.

There may be the plurality of first non-transmission areas NTA1. The plurality of first non-transmission areas NTA1 may extend in the first direction (or Y-axis direction) and may be spaced apart from each other in the second direction (or X-axis direction). The two adjacent first non-transmission areas NTA1 may be arranged to be spaced apart from each other with the transmission area TA interposed therebetween. For example, the transmission area TA may be arranged between the two adjacent first non-transmission areas NTA1. At least one first signal line extending in the first direction (or Y-axis direction) may be disposed in the first non-transmission area NTA1. For example, the at least one first signal line may be disposed to overlap the first non-transmission area NTA1. For example, the at least one first signal line may include at least one of a pixel power line VDDL (or first power line), a common power line VSSL (or second power line), a reference line REFL, and data lines DL, but embodiments of the present disclosure are not limited thereto.

The second non-transmission area NTA2 may extend in the second direction (or X-axis direction) in the display panel 110, and at least a portion of the second non-transmission area NTA2 may be disposed to overlap the emission areas EA1, EA2, EA3, and EA4 of each of the subpixels SP1, SP2, SP3, and SP4. For example, the second non-transmission area NTA2 may extend in the second direction (or X-axis direction) between the two adjacent first non-transmission areas NTA1. There may be the plurality of second non-transmission areas NTA2. The plurality of second non-transmission areas NTA2 may extend in the second direction (or X-axis direction) and may be spaced apart from each other in the first direction (or Y-axis direction). The two adjacent second non-transmission areas NTA2 may be arranged to be spaced apart from each other with the transmission area TA interposed therebetween. For example, the transmission area TA may be arranged between the two adjacent second non-transmission areas NTA2. At least one second signal line extending in the second direction (or X-axis direction) may be disposed in the second non-transmission area NTA2. For example, the at least one second signal line may be disposed to overlap the second non-transmission area NTA2. For example, the at least one second signal line may include a scan line SL (or gate line), but embodiments of the present disclosure are not limited thereto.

Each pixel P is disposed in each intersection where a first non-transmission area NTA1 and a second non-transmission area NTA2 intersect, and each pixel P emits light to display an image. Each pixel P may include emission areas EA1, EA2, EA3, and EA4 which emit light in response to the plurality of subpixels SP1, SP2, SP3, and SP4 including a light emitting element. The emission area EA1, EA2, EA3, and EA4 may correspond to an area in which light is emitted from the pixel P. The emission areas EA1, EA2, EA3, and EA4 may be disposed to overlap pixel circuits of the plurality of subpixels SP1, SP2, SP3, and SP4. For example, the emission areas EA1, EA2, EA3, and EA4 may at least partially overlap circuit areas CA1, CA2, CA3, and CA4 in which the pixel circuit is disposed. For example, the circuit areas CA1, CA2, CA3, and CA4 may include the first circuit area CA1 in which the pixel circuit connected to the first subpixel SP1 is disposed, the second circuit area CA2 in which the pixel circuit connected to the second subpixel SP2 is disposed, the third circuit area CA3 in which the pixel circuit connected to the third subpixel SP3 is disposed, and the fourth circuit area CA4 in which the pixel circuit connected to the fourth subpixel SP4 is disposed.

The first to fourth emission areas EA1, EA2, EA3, and EA4 corresponding to the plurality of subpixels SP1, SP2, SP3, and SP4 may emit light of different colors. For example, the first emission area EA1 may emit green light, the second emission area EA2 may emit blue light, the third emission area EA3 may emit white light, and the fourth emission area EA4 may emit red light, but embodiments of the present disclosure are not limited thereto. For example, the plurality of subpixels SP1, SP2, SP3, and SP4 may be configured in a quad type arranged in the first direction and the second direction (or X-axis direction) or a stripe type arranged in the first direction (or Y-axis direction), but not limited thereto. The arrangement order or type of the plurality of subpixels may be variously changed.

Referring to FIG. 4, The plurality of subpixels SP1, SP2, SP3, and SP4 according to an embodiment of the present disclosure may include the plurality of emission areas divided into the plurality. For example, the first electrode AE (pixel electrode or anode electrode) of each of the plurality of subpixels SP1, SP2, SP3, and SP4 may include the first divided electrode PAE1 (or first pixel divided electrode) and the second divided electrode PAE2 (or second pixel divided electrode) divided from each other. For example, the first divided electrode PAE1 and the second divided electrode PAE2 may be disposed spaced apart from each other in the first direction (or Y-axis direction) or the second direction (or X-axis direction). For example, as shown in FIG. 4, the first divided electrode PAE1 and the second divided electrode PAE2 may be disposed adjacent to each other in the first direction. Accordingly, the light emitting display apparatus according to an embodiment of the present disclosure may include a plurality of emission areas EA11, EA12, EA21, EA22, EA31, EA32, EA41, and EA42, where each emission area EA1, EA2, EA3, and EA4, included in a respective subpixel SP1, SP2, SP3, and SP4, is divided into two.

The circuit area CA1, CA2, CA3, and CA4 of the plurality of subpixels SP1, SP2, SP3, and SP4 may include a pixel circuit including at least one thin film transistor and a storage capacitor. For example, the at least one thin film transistor may include a driving transistor, a first switching transistor, and a second switching transistor, but embodiments of the present disclosure are not limited thereto. The pixel circuit of each of the plurality of subpixels SP1, SP2, SP3, and SP4 may be connected in common to the first divided electrode PAE1 and the second divided electrode PAE2.

Referring to FIG. 4, the first divided electrode PAE1 and the second divided electrode PAE2 according to an embodiment of the present disclosure may be electrically connected to a pixel circuit through a first branch pattern BP1 and a second branch pattern BP2. For example, the first divided electrode PAE1 may be electrically connected to the pixel circuit through the first branch pattern BP1 having a first sensing node, and the second divided electrode PAE2 may be electrically connected to the pixel circuit through the second branch pattern BP2 having a second sensing node different from the first sensing node. The first branch pattern BP1 may extend from the first divided electrode PAE1 in the second direction (or X-axis direction), and the second branch pattern BP2 may extend parallel to the first branch pattern BP1 in the second direction (or X-axis direction). The first branch pattern BP1 and the second branch pattern BP2 may be configured to have the same electrical length. The first branch pattern BP1 and the second branch pattern BP2 may be configured to have the same or different contact resistance from each other. For example, the first branch pattern BP1 and the second branch pattern BP2 may be configured to have the same contact resistance within an allowable error range. The first branch pattern BP1 and the second branch pattern BP2 may be configured to enable fine adjustment of the contact resistance.

The plurality of subpixels SP1, SP2, SP3, and SP4 may further include a connection pattern portion CPP connecting between at least one of the first branch pattern BP1 and the second branch pattern BP2 and the pixel circuit. The connection pattern portion CPP may electrically connect the first divided electrode PAE1 and the second divided electrode PAE2 to the circuit areas CA1, CA2, CA3, and CA4 of the respective subpixels SP1, SP2, SP3, and SP4. The connection pattern portion CPP may include a portion connected to the first branch pattern BP1 of the first divided electrode PAE1 and the second branch pattern BP2 of the second divided electrode PAE2, and a portion connected the circuit areas CA1, CA2, CA3, and CA4 of the respective subpixels SP1, SP2, SP3, and SP4.

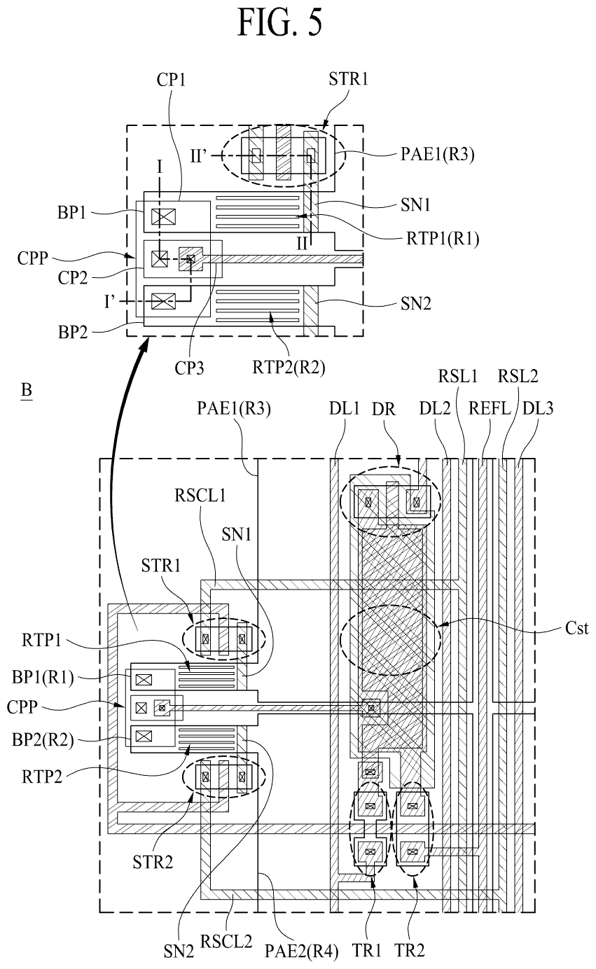

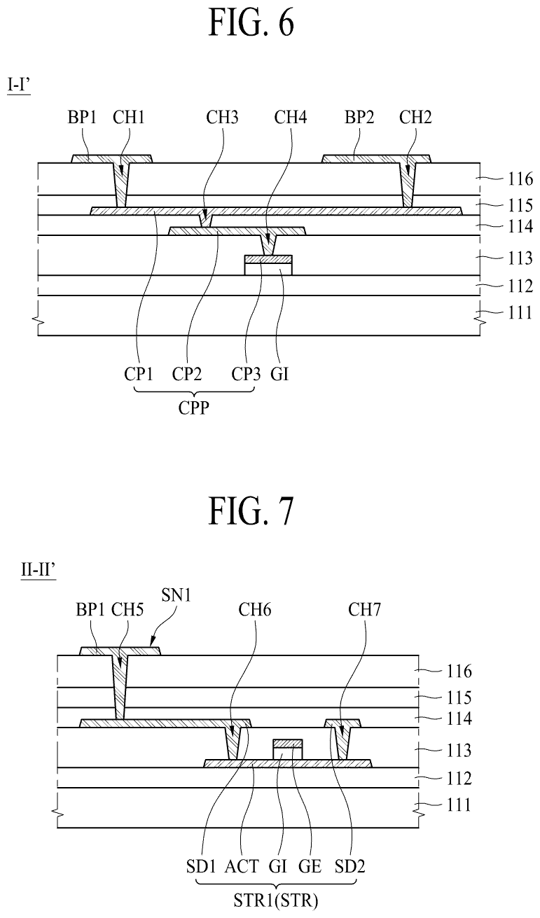

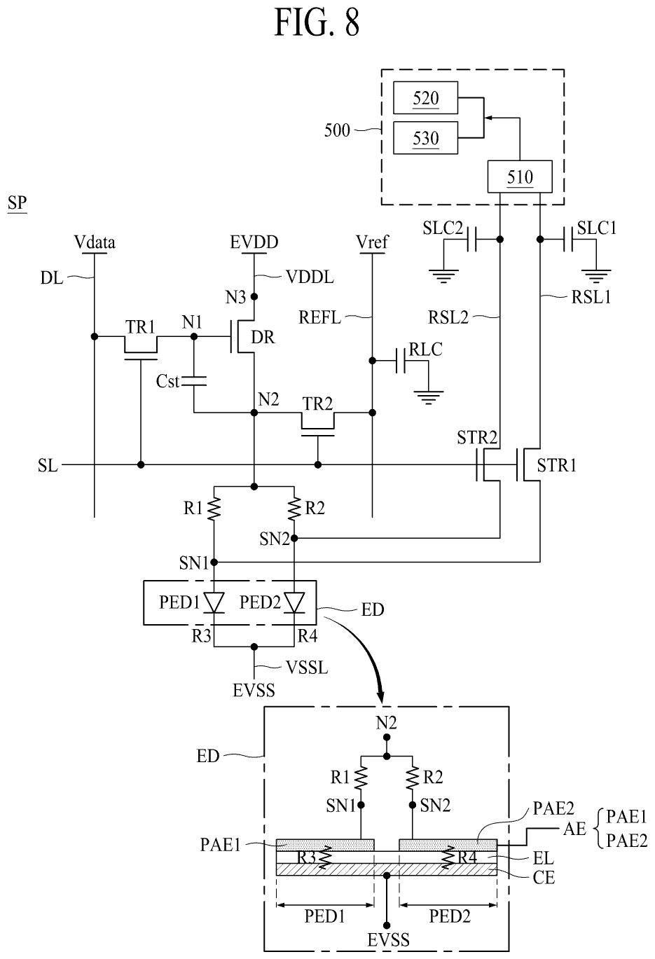

FIG. 5 illustrates a region B shown in FIG. 4 according to an embodiment of the present disclosure. FIG. 6 is a cross-sectional view taken along line I-I′ of FIG. 5 according to an embodiment of the present disclosure. FIG. 7 is a cross-sectional view taken along line II-II′ of FIG. 5 according to an embodiment of the present disclosure. FIG. 8 illustrates a subpixel and a repair detecting portion in a light emitting display apparatus according to an embodiment of the present disclosure.

Referring to FIGS. 5 to 8, the light emitting display apparatus according to an embodiment of the present disclosure may include a first and second divided electrodes PAE1 and PAE2 divided from each other, a first and second branch patterns BP1 and BP2 extending from the first and second divided electrodes PAE1 and PAE2, a pixel circuit comprising at least one thin film transistor DR, TR1, and TR2 and a storage capacitor Cst, and a connection pattern portion CPP connecting between the first and second branch patterns BP1 and BP2 and the pixel circuit.

The first and second divided electrodes PAE1 and PAE2 may be electrically connected to the pixel circuit through the first and second branch patterns BP1 and BP2, which have different sensing nodes SN1 and SN2. For example, the first divided electrode PAE1 may be electrically connected to the driving transistor DR of the pixel circuit through the first branch pattern BP1, which has the first sensing node SN1. The second divided electrode PAE2 may be electrically connected to the driving transistor DR of the pixel circuit through the second branch pattern BP2, which has the second sensing node SN2 different from the first sensing node SN1.

The first branch pattern BP1 may extend in a second direction (or X-axis direction) from one side of the first divided electrode PAE1, and the second branch pattern BP2 may extend in the second direction (or X-axis direction) from one side of the second divided electrode PAE2. The first and second branch patterns BP1 and BP2 may be spaced apart at a constant interval in a first direction (or Y-axis direction) and may extend parallel to each other in the second direction (or X-axis direction). The first and second branch patterns BP1 and BP2 may be configured to have the same electrical length. For example, the first and second branch patterns BP1 and BP2 may be configured to have the same shape.

The first and second branch patterns BP1 and BP2 may be configured to have the same or different contact resistances R1 and R2. For example, the first and second branch patterns BP1 and BP2 may be configured to have the same contact resistances R1 and R2 within an allowable error range. The first branch pattern BP1 may be configured to have a first contact resistance R1, and the second branch pattern BP2 may be configured to have a second contact resistance R2. The first and second contact resistances R1 and R2 of the first and second branch patterns BP1 and BP2 may be determined by a material or shape of the branch patterns BP1 and BP2, or by a contact area and contact structure between the branch patterns BP1 and BP2 and the connection pattern portion CPP. For example, the first contact resistance R1 may be determined by a size of a contact hole CH1 between the first branch pattern BP1 and the connection pattern portion CPP, and an area of an overlapping region between the first branch pattern BP1 and the connection pattern portion CPP. The second contact resistance R2 may be determined by a size of a contact hole CH2 between the second branch pattern BP2 and the connection pattern portion CPP, and an area of an overlapping region between the second branch pattern BP2 and the connection pattern portion CPP, but embodiments of the present disclosure are not limited thereto.

According to an embodiment of the present disclosure, the first and second branch patterns BP1, BP2 may include first and second sensing nodes SN1 and SN2 for detecting whether the first and second divided electrodes PAE1 and PAE2 are defective. The first and second sensing nodes SN1 and SN2 of the first and second branch patterns BP1 and BP2 may be configured to form the same or similar contact resistances R1 and R2. For example, the first and second contact resistances R1 and R2 may be configured to have resistance values of several tens of kΩ or more.

A defect of the first and second divided electrodes PAE1 and PAE2 may be detected based on the voltage measurement values of the first and second sensing nodes SN1 and SN2. For example, the defect of the first and second divided electrodes PAE1 and PAE2 may be detected based on the voltage measurement value of each of the first and second sensing nodes SN1 and SN2, or a voltage difference between the first and second sensing nodes SN1 and SN2.

For example, the defect of the first and second divided electrodes PAE1 and PAE2 may be detected using the principle of a Wheatstone bridge. The first and second sensing nodes SN1 and SN2 may be voltage output nodes of the Wheatstone bridge. The first and second sensing nodes SN1 and SN2 may detect the defect of the first and second divided electrodes PAE1 and PAE2 based on the Wheatstone bridge. For example, the Wheatstone bridge may be configured with the first and second contact resistances R1 and R2 of the first and second branch patterns BP1 and BP2, and resistances R3 and R4 of the first and second divided electrodes PAE1 and PAE2.

For example, the first sensing node SN1 may be a voltage output node between the first contact resistance R1 of the first branch pattern BP1 and the resistance R3 of the first divided electrode PAE1, and the second sensing node SN2 may be a voltage output node between the second contact resistance R2 of the second branch pattern BP2 and the resistance R4 of the second divided electrode PAE2. For example, the resistances R3 and R4 of the first and second divided electrodes PAE1 and PAE2 may be internal resistances of the partial light emitting elements PED1 and PED2, which include the first and second divided electrodes PAE1 and PAE2. For example, the resistances R3 and R4 of the first and second divided electrodes PAE1 and PAE2 may have resistance values ranging from 4 to 9 MΩ when the first and second partial light emitting elements PED1 and PED2 are operating normally. Also, the resistances R3 and R4 of the first and second divided electrodes PAE1 and PAE2 may have the same or similar resistance values when the first and second partial light emitting elements PED1 and PED2 are operating normally. In the Wheatstone bridge, when the first and second contact resistances R1 and R2 are identical, and the resistances R3 and R4 of the first and second divided electrodes PAE1 and PAE2 are also identical, the voltage measurement values of the first and second sensing nodes SN1 and SN2 may have the same voltage value, and the voltage difference between the first and second sensing nodes SN1 and SN2 may be 0V.

The light emitting display apparatus according to an embodiment of the present disclosure may configure the first and second contact resistances R1 and R2 of the first and second branch patterns BP1 and BP2 to have the same resistance value, and may configure voltage values measured from the first and second sensing nodes SN1 and SN2 under various state conditions of the first and second partial light emitting elements PED1 and PED2 as lookup data. As a result, the light emitting display apparatus according to an embodiment of the present disclosure may automatically detect a defect (or short circuit) occurring in either the first divided electrode PAE1 or the second divided electrode PAE2 based on the voltage measurement values of the first and second sensing nodes SN1 and SN2.

According to an embodiment of the present disclosure, the first and second branch patterns BP1 and BP2 may be configured to enable fine adjustment of the first and second contact resistances R1 and R2. The first and second branch patterns BP1 and BP2 may further include resistance trimming patterns RTP1 and RTP2 configured to enable fine adjustment of the first and second contact resistances R1 and R2. For example, the first branch pattern BP1 may include a first resistance trimming pattern RTP1, and the second branch pattern BP2 may include a second resistance trimming pattern RTP2.

The first and second branch patterns BP1 and BP2 may be configured to match the contact resistances R1 and R2 through the first and second resistance trimming patterns RTP1 and RTP2. For example, the first and second resistance trimming patterns RTP1 and RTP2 may serve to match the contact resistances R1 and R2 of the first and second branch patterns BP1 and BP2. For example, if the difference between the first and second contact resistances R1 and R2 of the first and second branch patterns BP1 and BP2 exceeds the allowable error range during the manufacturing process, the first and second contact resistances R1 and R2 may be matched through the first and second resistance trimming patterns RTP1 and RTP2.

The first and second resistance trimming patterns RTP1 and RTP2 may include a plurality of slit structures. For example, the plurality of slit structures may be configured to extend in a longitudinal direction of the first and second branch patterns BP1 and BP2 in at least a portion of the first and second branch patterns BP1 and BP2. The first and second resistance trimming patterns RTP1 and RTP2 may include at least three slit structures, but embodiments of the present disclosure are not limited thereto. The first and second resistance trimming patterns RTP1 and RTP2 may finely adjust resistance values of the first and second contact resistances R1 and R2 by removing some of the slit structures in the plurality of slit structures. For example, the first and second contact resistances R1 and R2 may be adjusted in a repair process by cutting some of the slit structures in the plurality of slit structures of the first and second resistance trimming patterns RTP1 and RTP2 using a laser. For example, the first and second contact resistances R1 and R2 may be adjusted by cutting some of the plurality of slit structures of the first and second resistance trimming patterns RTP1 and RTP2 with a laser in a repair process.

According to an embodiment of the present disclosure, when a resistance deviation occurs between the first and second contact resistances R1 and R2 of the first and second branch patterns BP1 and BP2 during the manufacturing process, the first and second contact resistances R1 and R2 may be matched with each other using the first and second resistance trimming patterns RTP1 and RTP2. As a result, by configuring the first and second contact resistances R1 and R2 to have more identical resistance values, the light emitting display apparatus may be implemented or realized to improve the reliability of detecting defects in the repair targets of the first and second divided electrodes PAE1 and PAE2.

The connection pattern portion CPP may be configured to connect between at least one of the first branch pattern BP1 and the second branch pattern BP2 and the pixel circuit. The connection pattern portion CPP may be configured to commonly connect the first branch pattern BP1 and the second branch pattern BP2 to the pixel circuit. For example, the connection pattern portion CPP may be configured to commonly connect the first branch pattern BP1 and the second branch pattern BP2 to the driving transistor DR of the pixel circuit.

Referring to FIGS. 5 and 6, the connection pattern portion CPP according to an embodiment of the present disclosure may include a plurality of connection patterns CP1, CP2, and CP3 disposed on different layers of a substrate 111. For example, the connection pattern portion CPP may include a first connection pattern CP1, a second connection pattern CP2, and a third connection pattern CP3.

The substrate 111 may include a buffer layer 112, an interlayer insulating layer 113, a first passivation layer 114, a second passivation layer 115, and a planarization layer 116.

The first connection pattern CP1 may overlap with the first and second branch patterns BP1 and BP2. The first connection pattern CP1 may be disposed on the first passivation layer 114, and may extend in a first direction (or Y-axis direction) that intersects with a second direction (or X-axis direction) in which the first and second branch patterns BP1 and BP2 are extended. The first connection pattern CP1 may extend in the first direction, one end of the first connection pattern CP1 may overlap with the first branch pattern BP1, and another end of the first connection pattern CP1 may overlap with the second branch pattern BP2. The planarization layer 116 and the second passivation layer 115 may be disposed between the first and second branch patterns BP1 and BP2 and the first connection pattern CP1. The first branch pattern BP1 may be connected to one end of the first connection pattern CP1 through a first contact hole CH1 that passes through the planarization layer 116 and the second passivation layer 115, and the second branch pattern BP2 may be connected to another end of the first connection pattern CP1 through a second contact hole CH2 that passes through the planarization layer 116 and the second passivation layer 115.

The second connection pattern CP2 may extend parallel to the first and second branch patterns BP1 and BP2. The second connection pattern CP2 may be configured to electrically connect between the first and second branch patterns BP1 and BP2 and the pixel circuit. The second connection pattern CP2 may be disposed on the interlayer insulating layer 113 and may extend in a second direction (or X-axis direction) parallel to the first and second branch patterns BP1 and BP2. The first passivation layer 114 may be disposed between the first connection pattern CP1 and the second connection pattern CP2. The first connection pattern CP1 may be connected to the second connection pattern CP2 through a third contact hole CH3 that passes through the first passivation layer 114.

The third connection pattern CP3 may extend parallel to the first and second branch patterns BP1 and BP2. The third connection pattern CP3 may be configured to electrically connect between the first and second branch patterns BP1 and BP2 and the pixel circuit. The third connection pattern CP3 may be disposed on the buffer layer 112. The third connection pattern CP3 may be configured to form the same material on the same layer as a gate electrode of at least one thin film transistor DR, TR1, and TR2. For example, the third connection pattern CP3 may be disposed on a gate insulating layer GI. The interlayer insulating layer 113 may be disposed between the second connection pattern CP2 and the third connection pattern CP3. The second connection pattern CP2 may be connected to the third connection pattern CP3 through a fourth contact hole CH4 that passes through the interlayer insulating layer 113.

Referring to FIGS. 5 and 7, the first and second sensing nodes SN1 and SN2 according to an embodiment of the present disclosure may be disposed between the connection pattern portion CPP and the first and second divided electrodes PAE1 and PAE2. The first sensing node SN1 may be disposed between the first contact hole CH1 and the first divided electrode PAE1 in the first branch pattern BP1. For example, the first sensing node SN1 may be disposed between the first resistance trimming pattern RTP1 and the first divided electrode PAE1 in the first branch pattern BP1. The second sensing node SN2 may be disposed between the second contact hole CH2 and the second divided electrode PAE2 in the second branch pattern BP2. For example, the second sensing node SN2 may be disposed between the second resistance trimming pattern RTP2 and the second divided electrode PAE2 in the second branch pattern BP2.

According to an embodiment of the present disclosure, the first and second sensing nodes SN1 and SN2 may be connected to the first sensing transistor STR1 and the second sensing transistor STR2. The first sensing node SN1 may be electrically connected to the first repair sensing line RSL1 through the first sensing transistor STR1. The second sensing node SN2 may be electrically connected to the second repair sensing line RSL2 through the second sensing transistor STR2. A first and second repair sensing connection lines RSCL1 and RSCL2 may further be included between the first and second sensing transistors STR1 and STR2 and the first and second repair sensing lines RSL1 and RSL2. For example, the first sensing transistor STR1 may be electrically connected to the first repair sensing line RSL1 through the first repair sensing connection line RSCL1, and the second sensing transistor STR2 may be electrically connected to the second repair sensing line RSL2 through the second repair sensing connection line RSCL2.

For example, the first and second repair sensing connection lines RSCL1 and RSCL2 and the first and second repair sensing lines RSL1 and RSL2 may be configured to form the same material on the same layer of the substrate 111, or different materials on different layers of the substrate 111, but embodiments of the present disclosure are not limited thereto. A jumping connection pattern may further be included between the first and second repair sensing connection lines RSCL1 and RSCL2 and the first and second repair sensing lines RSL1 and RSL2. The jumping connection pattern may electrically isolate from other signal lines and may be configured to electrically connect between the first and second repair sensing connection lines RSCL1 and RSCL2 with the first and second repair sensing lines RSL1 and RSL2, but embodiments of the present disclosure are not limited thereto.

The first sensing transistor STR1 may be disposed adjacent to the first branch pattern BP1, and the second sensing transistor STR2 may be disposed adjacent to the second branch pattern BP2. The first sensing transistor STR1 and the second sensing transistor STR2 may be configured identically or differently from each other. For example, the first and second sensing transistors STR1 and STR2 may be configured differently from each other depending on a connection method with the first and second repair sensing connection lines RSCL1 and RSCL2. For example, as shown in FIG. 7, the first sensing transistor STR1 (or the second sensing transistor STR2) may include an active layer ACT disposed on a buffer layer 112, a gate electrode GE disposed between the active layer ACT and a gate insulating layer GI, a first source/drain electrode SD1 connected to the first sensing node SN1 (or the second sensing node SN2), and a second source/drain electrode SD2 connected to the first repair sensing connection line RSCL1 (or the second repair sensing connection line RSCL2).

Referring to FIGS. 5 and 8, the light emitting display apparatus according to an embodiment of the present disclosure may include a plurality of data lines DL and at least one sensing line REFL, RSL1, and RSL2 extending in a first direction (or Y-axis direction), and a pixel circuit comprising at least one thin film transistor DR, TR1, and TR2 and a storage capacitor Cst. The plurality of data lines DL may include first to fourth data lines DL1, DL2, DL3, and DL4 corresponding to the plurality of subpixels SP1, SP2, SP3, and SP4 of each pixel P. The at least one sensing line REFL, RSL1, and RSL2 may include a reference line REFL, a first repair sensing line RSL1, and a second repair sensing line RSL2. The at least one thin film transistor DR, TR1, and TR2 may include a driving transistor DR, a first switching transistor TR1, and a second switching transistor TR2.

Referring to FIG. 8, the light emitting display apparatus according to an embodiment of the present disclosure may further include a repair detection portion 500 electrically connected to the first and second sensing nodes SN1 and SN2.

The first sensing node SN1 may be electrically connected to the repair detection portion 500 through the first sensing transistor STR1 and the first repair sensing line RSL1, and the second sensing node SN2 may be electrically connected to the repair detection portion 500 through the second sensing transistor STR2 and the second repair sensing line RSL2.

The repair detection portion 500 may sense a voltage of the first sensing node SN1 through the first repair sensing line RSL1 connected to the first sensing node SN1, and may sense a voltage of the second sensing node SN2 through the second repair sensing line RSL2 connected to the second sensing node SN2. The first repair sensing line RSL1 may include a line capacitor SLC1 that stores the voltage of the first sensing node SN1, and the second repair sensing line RSL2 may include a line capacitor SLC2 that stores the voltage of the second sensing node SN2. Also, the reference line REFL may include a line capacitor RLC that stores a voltage of the second node N2 of the driving transistor DR.

The repair detection portion 500 may detect defects in the first divided electrode PAE1 and the second divided electrode PAE2 based on a voltage measurement value of the first sensing node SN1 and a voltage measurement value of the second sensing node SN2. For example, the repair detection portion 500 may detect defects in the first divided electrode PAE1 and the second divided electrode PAE2 based on a voltage difference between the first sensing node SN1 and the second sensing node SN2.

The repair detection portion 500 may further include a sensing portion 510 for measuring voltages of the first repair sensing line RSL1 and the second repair sensing line RSL2, a detection portion 520 for detecting defects in the first divided electrode PAE1 and the second divided electrode PAE2 based on a voltage measurement value measured by the sensing portion 510, and a memory 530 for storing the detection result of the detecting portion 520 and information related thereto.

The sensing portion 510 of the repair detection portion 500 may measure a voltage of the first sensing node SN1, which is between the first contact resistance R1 of the first branch pattern BP1 and the resistance R3 of the first divided electrode PAE1, and a voltage of the second sensing node SN2, which is between the second contact resistance R2 of the second branch pattern BP2 and the resistance R4 of the second divided electrode PAE2, both of which are configured as a Wheatstone bridge.

The sensing portion 510 of the repair detection portion 500 may detect defects in the first divided electrode PAE1 and the second divided electrode PAE2 using the voltage measurement values of the first and second sensing nodes SN1 and SN2 measured by the sensing portion 510 and lookup data stored in the memory 530. For example, the lookup data stored in the memory 530 may be configured with voltage values measured from the first and second sensing nodes SN1 and SN2 under various state conditions of the first and second partial light emitting element PED1 and PED2, after configuring the first and second contact resistances R1 and R2 having the same resistance values in advance.

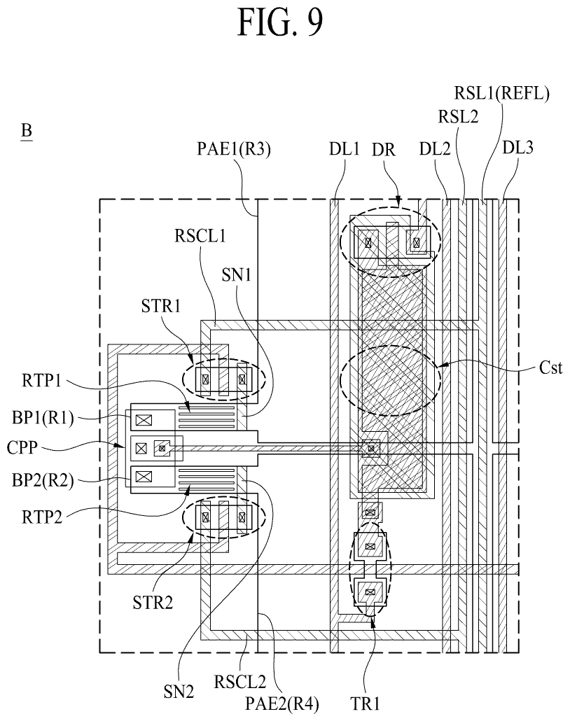

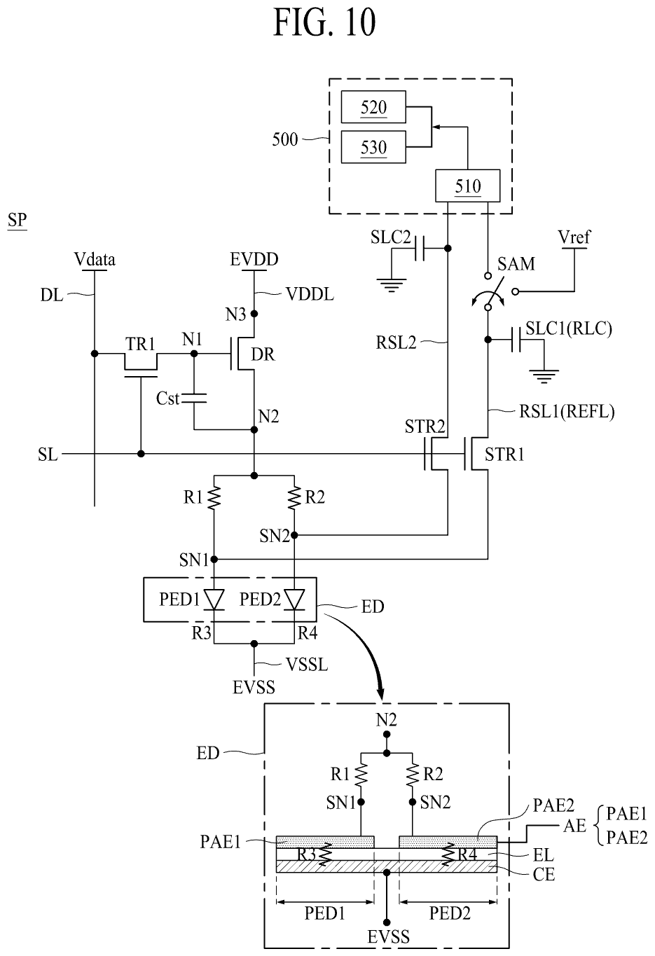

FIG. 9 illustrates a region B shown in FIG. 4 according to another embodiment of the present disclosure. FIG. 10 illustrates a subpixel and a repair detecting portion in a light emitting display apparatus according to another embodiment of the present disclosure. FIGS. 9 and 10 illustrate embodiments in which the configuration of the pixel circuit and the repair detection portion in the light emitting display apparatus, described with reference to FIGS. 1 to 8, is modified. In the following description with reference to FIGS. 9 and 10, the same reference numerals are assigned to the remaining components except for the changed configuration, and a redundant description thereof will be omitted or briefly described.

Referring to FIGS. 9 and 10, the light emitting display apparatus according to another embodiment of the present disclosure may include a pixel circuit comprising a plurality of data lines DL extending in a first direction (or Y direction), at least one sensing line RSL1 and RSL2, at least one thin film transistor DR and TR1, and a storage capacitor Cst. The plurality of data lines DL may include first to fourth data lines DL1, DL2, DL3, and DLA corresponding to the plurality of subpixels SP1, SP2, SP3, and SP4 of each pixel P. At least one sensing line RSL1 and RSL2 may include a first repair sensing line RSL1 and a second repair sensing line RSL2. For example, the first repair sensing line RSL1 may share the role of a reference line REFL. At least one thin film transistor DR and TR1 may include a driving transistor DR and a first switching transistor TR1.

The first sensing node SN1 may be electrically connected to the repair detection portion 500 through the first sensing transistor STR1 and the first repair sensing line RSL1 (or the reference line REFL), and the second sensing node SN2 may be electrically connected to the repair detection portion 500 through the second sensing transistor STR2 and the second repair sensing line RSL2.

The repair detection portion 500 may sense a voltage of the first sensing node SN1 through the first repair sensing line RSL1 connected to the first sensing node SN1, and may sense a voltage of the second sensing node SN2 through the second repair sensing line RSL2 connected to the second sensing node SN2. The first repair sensing line RSL1 may include a line capacitor SLC1 that stores the voltage of the first sensing node SN1, and the second repair sensing line RSL2 may include a line capacitor SLC2 that stores the voltage of the second sensing node SN2. Also, the first repair sensing line RSL1 may share the role of the reference line REFL and may include a line capacitor RLC that stores the voltage of the second node N2 of the driving transistor DR. For example, during a display driving period of the light emitting display apparatus, the first repair sensing line RSL1 may function as the reference line REFL to initialize the second node N2 of the driving transistor DR or output the voltage of the second node N2 of the driving transistor DR. Alternatively, during a repair detection period of the light emitting display apparatus, the first repair sensing line RSL1 may function as a sensing line to output the voltage of the first sensing node SN1 for detecting a repair target.

The repair detection portion 500 may further include a sampling switch SAM for controlling the role of the first repair sensing line RSL1. For example, the sampling switch SAM may be controlled to apply a reference voltage Vref to the first repair sensing line RSL1 during the display driving period. Alternatively, the sampling switch SAM may be controlled to connect the first repair sensing line RSL1 to the sensing portion 510 during the repair detection period.

According to another embodiment of the present disclosure, the first sensing transistor STR1 may supply the reference voltage Vref applied from the first repair sensing line RSL1 to the second node N2 of the driving transistor DR in the display driving period, or may output the voltage of the second node N2 of the driving transistor DR. Also, the first sensing transistor STR1 may output the voltage of the first sensing node SN1 to the repair detection portion 500 in the repair detection period.

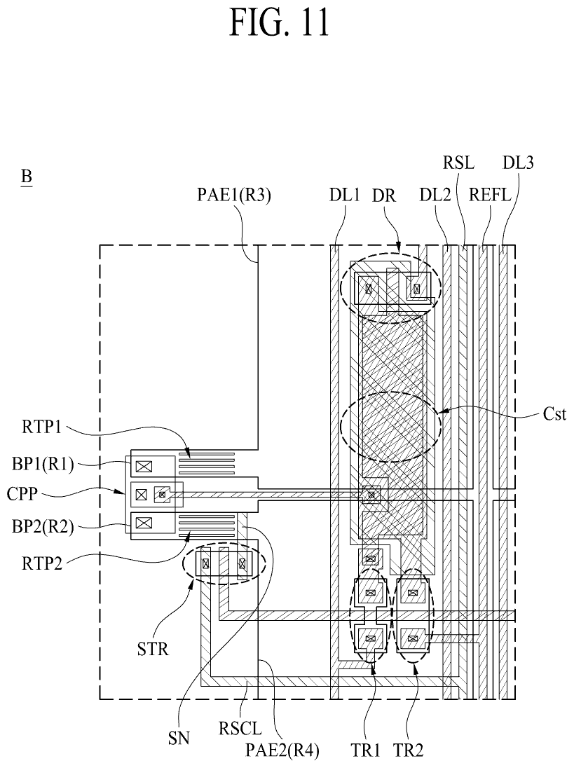

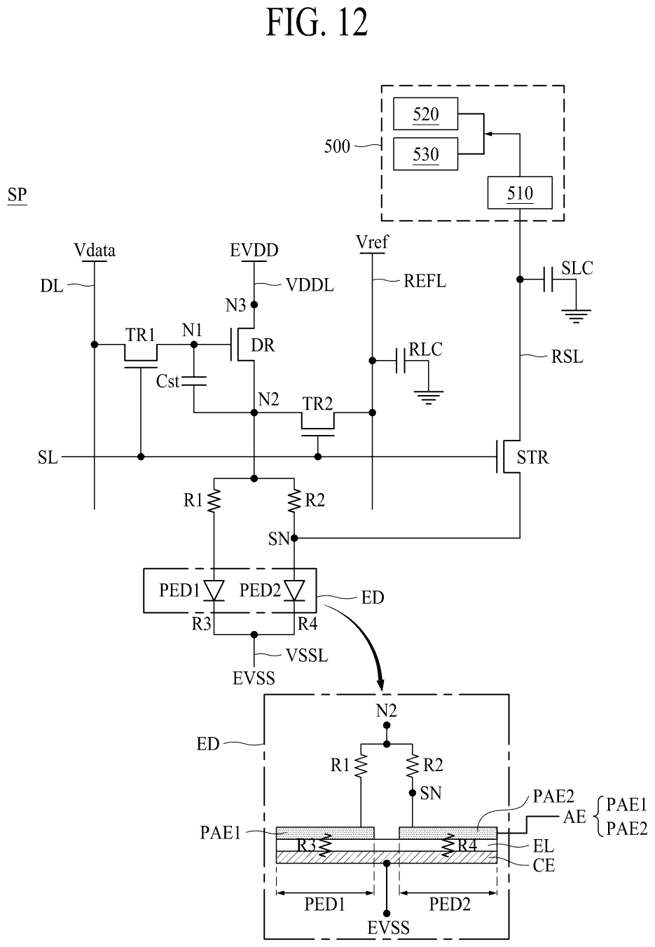

FIG. 11 illustrates a region B shown in FIG. 4 according to another embodiment of the present disclosure. FIG. 12 illustrates a subpixel and a repair detecting portion in a light emitting display apparatus according to another embodiment of the present disclosure. FIGS. 11 and 12 illustrate embodiments in which the configuration of the pixel circuit and the repair detection portion in the light emitting display apparatus, described with reference to FIGS. 1 to 10, is modified. In the following description with reference to FIGS. 11 and 12, the same reference numerals are assigned to the remaining components except for the changed configuration, and a redundant description thereof will be omitted or briefly described.

Referring to FIGS. 11 and 12, the light emitting display apparatus according to another embodiment of the present disclosure may include a pixel circuit comprising a plurality of data lines DL extending in a first direction (or Y direction), at least one sensing line RSL and REFL, at least one thin film transistor DR, TR1, and TR2, and a storage capacitor Cst. The plurality of data lines DL may include first to fourth data lines DL1, DL2, DL3, and DL4 corresponding to the plurality of subpixels SP1, SP2, SP3, and SP4 of each pixel P. At least one sensing line RSL and REFL may include a repair sensing line RSL and a reference line REFL. At least one thin film transistor DR, TR1, and TR2 may include a driving transistor DR, a first switching transistor TR1, and a second switching transistor TR2.

According to another embodiment of the present disclosure, either the first and second branch patterns BP1 and BP2 may include a sensing node SN. For example, the sensing node SN may be disposed between a second contact hole CH2 and the second divided electrode PAE2 in the second branch pattern BP2. For example, the sensing node SN may be disposed between the second resistance trimming pattern RTP2 and the second divided electrode PAE2 in the second branch pattern BP2. Meanwhile, although the sensing node SN is illustrated as being disposed in the second branch pattern BP2 in FIGS. 11 and 12, the sensing node SN may also be disposed in the first branch pattern BP1, and embodiments of the present disclosure are not limited thereto.

According to another embodiment of the present disclosure, the sensing node SN may be connected to a sensing transistor STR. The sensing node SN may be electrically connected to the repair sensing line RSL through the sensing transistor STR. A repair sensing connection line RSCL may further be included between the sensing transistor STR and the repair sensing line RSL.

Referring to FIG. 12, the light emitting display apparatus according to another embodiment of the present disclosure may further include a repair detection portion 500 electrically connected to the sensing node SN.

The sensing node SN may be electrically connected to the repair detection portion 500 through the sensing transistor STR and the repair sensing line RSL.

The repair detection portion 500 may sense the voltage of the sensing node SN through the repair sensing line RSL connected to the sensing node SN. The repair sensing line RSL may include a line capacitor SLC that stores the voltage of the sensing node SN. Also, the reference line REFL may include a line capacitor RLC that stores the voltage of the second node N2 of the driving transistor DR.

The repair detection portion 500 may detect defects in the first divided electrode PAE1 and the second divided electrode PAE2 based on a voltage measurement value of the sensing node SN. For example, the repair detection portion 500 may configure the first and second contact resistances R1 and R2 to have the same resistance values in advance, and then, using lookup data composed of voltage values measured from the sensing node SN under various state conditions of the first and second partial light emitting elements PED1 and PED2, may detect defects in the first divided electrode PAE1 and the second divided electrode PAE2.

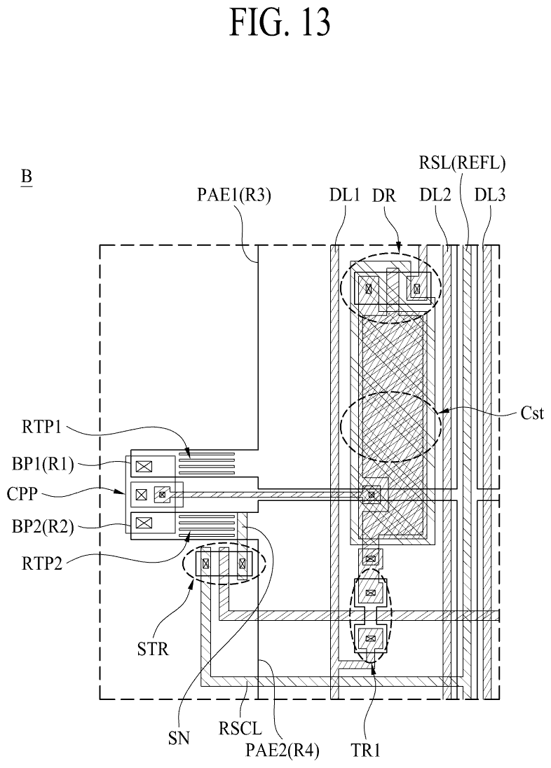

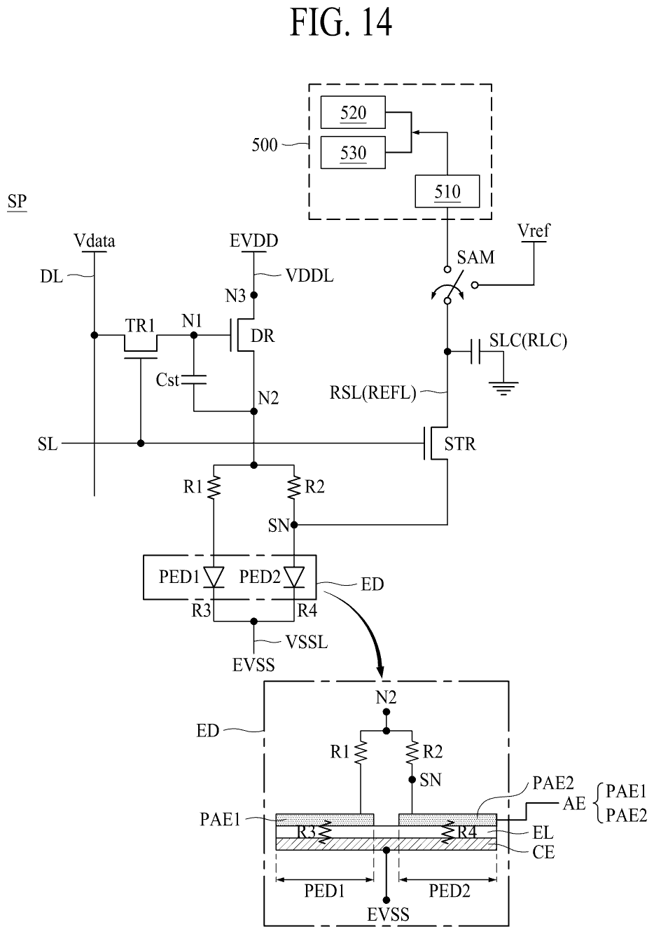

FIG. 13 illustrates a region B shown in FIG. 4 according to another embodiment of the present disclosure. FIG. 14 illustrates a subpixel and a repair detecting portion in a light emitting display apparatus according to another embodiment of the present disclosure. FIGS. 13 and 14 illustrate embodiments in which the configuration of the pixel circuit and the repair detection portion in the light emitting display apparatus, described with reference to FIGS. 1 to 12, is modified. In the following description with reference to FIGS. 13 and 14, the same reference numerals are assigned to the remaining components except for the changed configuration, and a redundant description thereof will be omitted or briefly described.

Referring to FIGS. 13 and 14, the light emitting display apparatus according to another embodiment of the present disclosure may include a pixel circuit comprising a plurality of data lines DL extending in a first direction (or Y direction), at least one sensing line RSL, at least one thin film transistor DR, TR1, and a storage capacitor Cst. The plurality of data lines DL may include first to fourth data lines DL1, DL2, DL3, and DLA corresponding to the plurality of subpixels SP1, SP2, SP3, and SP4 of each pixel P. At least one sensing line RSL may include a repair sensing line RSL. For example, the repair sensing line RSL may share the role of a reference line REFL. At least one thin film transistor DR and TR1 may include a driving transistor DR and a first switching transistor TR1.

According to another embodiment of the present disclosure, either the first and second branch patterns BP1 and BP2 may include a sensing node SN. For example, the sensing node SN may be disposed between a second contact hole CH2 and the second divided electrode PAE2 in the second branch pattern BP2. For example, the sensing node SN may be disposed between the second resistance trimming pattern RTP2 and the second divided electrode PAE2 in the second branch pattern BP2. Meanwhile, although the sensing node SN is illustrated as being disposed in the second branch pattern BP2 in FIGS. 13 and 14, the sensing node SN may also be disposed in the first branch pattern BP1, and embodiments of the present disclosure are not limited thereto.

According to another embodiment of the present disclosure, the sensing node SN may be connected to a sensing transistor STR. The sensing node SN may be electrically connected to the repair sensing line RSL through the sensing transistor STR. A repair sensing connection line RSCL may be included between the sensing transistor STR and the repair sensing line RSL.

The repair detection portion 500 may sense a voltage of the sensing node SN through the repair sensing line RSL connected to the sensing node SN. The repair sensing line RSL may include a line capacitor SLC that stores the voltage of the sensing node SN. Additionally, the repair sensing line RSL may share the role of the reference line REFL and may include a line capacitor RLC that stores the voltage of the second node N2 of the driving transistor DR. For example, during the display driving period of the light emitting display apparatus, the repair sensing line RSL may function as the reference line REFL to initialize the second node N2 of the driving transistor DR or output the voltage of the second node N2 of the driving transistor DR. Alternatively, during the repair detection period of the light emitting display apparatus, the repair sensing line RSL may function as a sensing line to output the voltage of the sensing node SN for detecting a repair target.

The repair detection portion 500 may further include a sampling switch SAM for controlling the role of the repair sensing line RSL. For example, the sampling switch SAM may be controlled to apply a reference voltage Vref to the repair sensing line RSL during the display driving period. Alternatively, the sampling switch SAM may be controlled to connect the repair sensing line RSL to the sensing portion 510 during the repair detection period.

According to another embodiment of the present disclosure, the sensing transistor STR may supply the reference voltage Vref applied from the repair sensing line RSL to the second node N2 of the driving transistor DR in the display driving period, or may output the voltage of the second node N2 of the driving transistor DR. Also, the sensing transistor STR may output the voltage of the sensing node SN to the repair detection portion 500 in the repair detection period.

The repair detection portion 500 may detect defects in the first divided electrode PAE1 and the second divided electrode PAE2 based on a voltage measurement value of the sensing node SN. For example, the repair detection portion 500 may configure the first and second contact resistances R1 and R2 to have the same resistance values in advance, and then, using lookup data composed of voltage values measured from the sensing node SN under various state conditions of the first and second partial light emitting elements PED1 and PED2, may detect defects in the first divided electrode PAE1 and the second divided electrode PAE2.

A light emitting display apparatus according to one or more embodiments of the present disclosure will be described below.

A light emitting display apparatus according to one or more embodiments of the present disclosure may include a light emitting element including a pixel electrode, an emission layer, and a common electrode, a first branch pattern having a first sensing node, a second branch pattern having a second sensing node, and a pixel circuit connected to the pixel electrode and configured to include at least one thin film transistor, the pixel electrode may include a first pixel divided electrode and a second pixel divided electrode spaced apart from each other, the first pixel divided electrode may be connected to the pixel circuit through the first branch pattern having the first sensing node, and the second pixel divided electrode may be connected to the pixel circuit through the second branch pattern having the second sensing node different from the first sensing node.

According to one or more embodiments of the present disclosure, the first branch pattern and the second branch pattern may be configured to have either the same or different contact resistance from each other.

According to one or more embodiments of the present disclosure, the first branch pattern and the second branch pattern may be configured to have the same contact resistance within an allowable error range.

According to one or more embodiments of the present disclosure, the first branch pattern and the second branch pattern may further include a resistance trimming pattern configured to enable fine adjustment of contact resistance.

According to one or more embodiments of the present disclosure, the first branch pattern and the second branch pattern may be configured to match the contact resistance through the resistance trimming pattern.

According to one or more embodiments of the present disclosure, the resistance trimming pattern may include a plurality of slit structures.

According to one or more embodiments of the present disclosure, the contact resistance may be adjusted by some of the plurality of slit structures of the resistance trimming pattern being laser cut.

According to one or more embodiments of the present disclosure, the pixel circuit may be commonly connected to the first branch pattern and the second branch pattern.

According to one or more embodiments of the present disclosure, the first branch pattern may extend in a first direction from the first pixel divided electrode, and the second branch pattern may extend parallel to the first branch pattern in the first direction.

According to one or more embodiments of the present disclosure, the first branch pattern and the second branch pattern may be configured to have a same electrical length.

According to one or more embodiments of the present disclosure, the light emitting display apparatus may further include a connection pattern portion connecting between at least one of the first and second branch patterns and the pixel circuit.

According to one or more embodiments of the present disclosure, the connection pattern portion may include a first connection pattern overlapping with the first branch pattern and the second branch pattern, and a second connection pattern extending parallel to the first branch pattern and the second branch pattern, and connecting between the first connection pattern and the pixel circuit.

According to one or more embodiments of the present disclosure, at least one insulating layer may be provided between the first and second branch patterns and the first connection pattern, the first branch pattern may be connected to one end of the first connection pattern through a first contact hole passing through the at least one insulating layer, and the second branch pattern may be connected to another end of the first connection pattern through a second contact hole passing through the at least one insulating layer.

According to one or more embodiments of the present disclosure, the first sensing node may be between the first contact hole and the first pixel divided electrode, and the second sensing node may be between the second contact hole and the second pixel divided electrode.

According to one or more embodiments of the present disclosure, the first branch pattern and the second branch pattern may further include a resistance trimming pattern, the first sensing node may be between the resistance trimming pattern of the first branch pattern and the first pixel divided electrode, and the second sensing node may be between the resistance trimming pattern of the second branch pattern and the second pixel divided electrode.

According to one or more embodiments of the present disclosure, the light emitting display apparatus may further include a repair detection portion electrically connected to at least one of the first sensing node and the second sensing node.

According to one or more embodiments of the present disclosure, the repair detection portion may be configured to detect a defect of the first pixel divided electrode and the second pixel divided electrode based on a voltage measurement value of at least one of the first sensing node and the second sensing node.

According to one or more embodiments of the present disclosure, the repair detection portion may be configured to sense a voltage of the first sensing node through a first sensing line connected to the first sensing node, sense a voltage of the second sensing node through a second sensing line connected to the second sensing node, and detect a defect of the first pixel divided electrode and the second pixel divided electrode based on a voltage measurement value of the first sensing node and a voltage measurement value of the second sensing node.

According to one or more embodiments of the present disclosure, the first sensing node and the second sensing node may be configured to sense a voltage concurrently (or in some embodiments, simultaneously).

According to one or more embodiments of the present disclosure, the pixel circuit may include a driving transistor including a gate electrode connected to a first node, a first electrode connected to a second node common to the first and second sensing nodes, a second electrode connected to a third node to which a pixel power voltage is applied, and configured to generate a driving current according to a gate-to-source voltage, and a switching transistor connected between a data line to which a data voltage is applied and the first node.

According to one or more embodiments of the present disclosure, the pixel circuit may further include at least one sensing transistor connecting between at least one of the second node, the first sensing node, and the second sensing node and the repair detection portion.

According to one or more embodiments of the present disclosure, a sensing transistor connected to the first sensing node of the at least one sensing transistor may be disposed adjacent to the first branch pattern, and a sensing transistor connected to the second sensing node of the at least one sensing transistor may be disposed adjacent to the second branch pattern.

According to one or more embodiments of the present disclosure, the repair detection portion may be configured to detect a defect using a Wheatstone bridge configuration formed by contact resistances of the first and second branch patterns and pixel divided electrodes.

The above-described feature, structure, and effect of the present disclosure are included in at least one embodiment of the present disclosure, but are not limited to only one embodiment. Furthermore, the feature, structure, and effect described in at least one embodiment of the present disclosure may be implemented through combination or modification of other embodiments by those skilled in the art. Therefore, content associated with the combination and modification should be construed as being within the scope of the present disclosure.

It will be apparent to those skilled in the art that various modifications and variations can be made in the present disclosure without departing from the spirit or scope of the disclosures. Thus, it is intended that the present disclosure covers the modifications and variations of this disclosure provided they come within the scope of the appended claims and their equivalents.

The various embodiments described above can be combined to provide further embodiments. These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A light emitting display apparatus comprising:
a light emitting element including a pixel electrode, an emission layer, and a common electrode;
a first branch pattern having a first sensing node;
a second branch pattern having a second sensing node; and
a pixel circuit connected to the pixel electrode and configured to include at least one thin film transistor,
wherein the pixel electrode includes a first pixel divided electrode and a second pixel divided electrode spaced apart from each other,
wherein the first pixel divided electrode is connected to the pixel circuit through the first branch pattern having the first sensing node, and
wherein the second pixel divided electrode is connected to the pixel circuit through the second branch pattern having the second sensing node different from the first sensing node.

2. The light emitting display apparatus of claim 1, wherein the first branch pattern and the second branch pattern are configured to have either the same or different contact resistance from each other.

3. The light emitting display apparatus of claim 2, wherein the first branch pattern and the second branch pattern are configured to have the same contact resistance within an allowable error range.

4. The light emitting display apparatus of claim 1, wherein the first branch pattern and the second branch pattern further include a resistance trimming pattern configured to enable fine adjustment of contact resistance.

5. The light emitting display apparatus of claim 4, wherein the first branch pattern and the second branch pattern are configured to match the contact resistance through the resistance trimming pattern.

6. The light emitting display apparatus of claim 4, wherein the resistance trimming pattern includes a plurality of slit structures.

7. The light emitting display apparatus of claim 6, wherein the contact resistance is adjusted by some of the plurality of slit structures of the resistance trimming pattern being laser cut.

8. The light emitting display apparatus of claim 1, wherein the pixel circuit is commonly connected to the first branch pattern and the second branch pattern.

9. The light emitting display apparatus of claim 1, wherein the first branch pattern extends in a first direction from the first pixel divided electrode, and the second branch pattern extends parallel to the first branch pattern in the first direction.

10. The light emitting display apparatus of claim 9, wherein the first branch pattern and the second branch pattern are configured to have a same electrical length.

11. The light emitting display apparatus of claim 1, further comprising a connection pattern portion connecting between at least one of the first and second branch patterns and the pixel circuit.

12. The light emitting display apparatus of claim 11, wherein the connection pattern portion comprises:
a first connection pattern overlapping with the first branch pattern and the second branch pattern; and
a second connection pattern extending parallel to the first branch pattern and the second branch pattern, and connecting between the first connection pattern and the pixel circuit.

13. The light emitting display apparatus of claim 12, wherein at least one insulating layer is provided between the first and second branch patterns and the first connection pattern,
wherein the first branch pattern is connected to one end of the first connection pattern through a first contact hole passing through the at least one insulating layer, and
wherein the second branch pattern is connected to another end of the first connection pattern through a second contact hole passing through the at least one insulating layer.

14. The light emitting display apparatus of claim 13, wherein the first sensing node is between the first contact hole and the first pixel divided electrode, and the second sensing node is between the second contact hole and the second pixel divided electrode.

15. The light emitting display apparatus of claim 14, wherein the first branch pattern and the second branch pattern further comprise a resistance trimming pattern,
wherein the first sensing node is between the resistance trimming pattern of the first branch pattern and the first pixel divided electrode, and
wherein the second sensing node is between the resistance trimming pattern of the second branch pattern and the second pixel divided electrode.

16. The light emitting display apparatus of claim 1, further comprising a repair detection portion connected to at least one of the first sensing node and the second sensing node.

17. The light emitting display apparatus of claim 16, wherein the repair detection portion is configured to detect a defect of the first pixel divided electrode and the second pixel divided electrode based on a voltage measurement value of at least one of the first sensing node and the second sensing node.

18. The light emitting display apparatus of claim 16, wherein the repair detection portion is configured to:
sense a voltage of the first sensing node through a first sensing line connected to the first sensing node,
sense a voltage of the second sensing node through a second sensing line connected to the second sensing node, and
detect a defect of the first pixel divided electrode and the second pixel divided electrode based on a voltage measurement value of the first sensing node and a voltage measurement value of the second sensing node.

19. The light emitting display apparatus of claim 18, wherein the first sensing node and the second sensing node are configured to sense a voltage concurrently.

20. The light emitting display apparatus of claim 16, wherein the pixel circuit comprises:
a driving transistor including a gate electrode connected to a first node, a first electrode connected to a second node common to the first and second sensing nodes, a second electrode connected to a third node to which a pixel power voltage is applied, and configured to generate a driving current according to a gate-to-source voltage; and
a switching transistor connected between a data line to which a data voltage is applied and the first node.

21. The light emitting display apparatus of claim 20, wherein the pixel circuit further comprises at least one sensing transistor connecting between at least one of the second node, the first sensing node, and the second sensing node and the repair detection portion.

22. The light emitting display apparatus of claim 21, wherein a sensing transistor connected to the first sensing node of the at least one sensing transistor is disposed adjacent to the first branch pattern, and a sensing transistor connected to the second sensing node of the at least one sensing transistor is disposed adjacent to the second branch pattern.

23. The light emitting display apparatus of claim 18, wherein the repair detection portion is configured to detect a defect using a Wheatstone bridge configuration formed by contact resistances of the first and second branch patterns and pixel divided electrodes.
